(19) United States
(12) Patent Application Publication
(10) Pub. No.: US 2025/0008851 A1
(43) Pub. Date: Jan. 2, 2025

(54) SEMICONDUCTOR DEVICE INCLUDING MEMORY CELL HAVING SELECTOR

(71) Applicant: SK hynix Inc., Icheon-si (KR)

(72) Inventors: Jeong Myeong KIM, Icheon-si (KR); Cha Deok DONG, Icheon-si (KR); Keo Rock CHOI, Icheon-si (KR)

(21) Appl. No.: 18/393,513

(22) Filed: Dec. 21, 2023

(30) Foreign Application Priority Data
Jun. 29, 2023 (KR) 10-2023-0084254

(51) Int. Cl. H10N 70/00; H10B 63/00

(52) U.S. Cl. CPC H10N 70/883; H10B 63/00; H10N 70/841

(57) ABSTRACT

A semiconductor device includes a plurality of memory cells. Each memory cell includes: a first electrode layer; a second electrode layer; a memory layer electrically connected to the second electrode layer and configured to store data; a selector layer interposed between the first electrode layer and the second electrode layer and configured to control an access to the memory layer, the selector layer including an insulating material layer doped with a dopant, wherein at least one of the first electrode layer and the second electrode layer includes a first sub-electrode layer, and a second sub-electrode layer interposed between the first sub-electrode layer and the selector layer and including a material having a work function greater than a work function of the first sub-electrode layer.

### PRIORITY CLAIM AND CROSS-REFERENCE TO RELATED APPLICATION

This patent document claims priority under 35 U.S.C. § 119 to Korean Patent Application No. 10-2023-0084254 filed on Jun. 29, 2023, which is incorporated herein by reference in its entirety.

### TECHNICAL FIELD

This patent document relates to a semiconductor technology, and particularly, to a semiconductor device including a memory cell having a selector.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

In an embodiment, a semiconductor device may include a plurality of memory cells. Each memory cell may include: a first electrode layer; a second electrode layer; a memory layer electrically connected to the second electrode layer and configured to store data; a selector layer interposed between the first electrode layer and the second electrode layer and configured to control an access to the memory layer, the selector layer including an insulating material layer doped with a dopant, wherein at least one of the first electrode layer and the second electrode layer includes a first sub-electrode layer, and a second sub-electrode layer interposed between the first sub-electrode layer and the selector layer and including a material having a work function greater than a work function of the first sub-electrode layer.

In another embodiment, a semiconductor device may include a plurality of memory cells. Each memory cell may include: a first electrode layer; a second electrode layer; a memory layer electrically connected to the second electrode layer and configured to store data; a selector layer interposed between the first electrode layer and the second electrode layer and configured to control an access to the memory layer, the selector layer including an insulating material layer doped with a dopant; a material layer located at least one of a first location between the first electrode layer and the selector layer or a second location between the second electrode layer and the selector layer, and having a band gap smaller than a band gap of the insulating material layer.

In another embodiment, a semiconductor device may include a plurality of memory cells. Each memory cell may include: a first electrode layer; a second electrode layer; a memory layer electrically connected to the second electrode layer and configured to store data; and a selector layer interposed between the first electrode layer and the second electrode layer and configured to control an access to the memory layer, the selector layer including an insulating material layer doped with a dopant, wherein at least one of the first electrode layer and the second electrode layer includes a first sub-electrode layer and a second sub-electrode layer interposed between the first sub-electrode layer and the selector layer, and at least one of a density, a mass of a constituent element, or a size of the constituent element of the second sub-electrode layer is greater than, respectively, a density, a mass of a constituent element, or a size of the constituent element of the first sub-electrode layer.

### BRIEF DESCRIPTION OF THE DRAWINGS

FIG. 1 is a perspective view illustrating a semiconductor device according to an embodiment of the present disclosure.

FIG. 2 is a cross-sectional view showing an example of a selector portion of a memory cell of the semiconductor device of FIG. 1.

FIG. 3A is an energy band diagram illustrating an operation of a selector portion of a comparative example.

FIG. 3B is an energy band diagram illustrating an operation of a selector portion of the present embodiment.

FIGS. 4A and 4B are cross-sectional views illustrating a method for forming the selector portion of FIG. 2.

FIG. 5 is a view showing an effective thickness and leakage current characteristics of a selector portion in the present embodiment and comparative examples.

FIG. 6 is a view showing a sheet resistance of an electrode of a selector portion and a sheet resistance of the selector portion as a whole in the present embodiment and comparative examples.

FIG. 7 is a view showing a roughness of a selector portion in the present embodiment and comparative examples.

FIG. 8 is a cross-sectional view illustrating another example of a selector portion of a memory cell of the semiconductor device of FIG. 1.

FIG. 9 is a cross-sectional view illustrating another example of a selector portion of a memory cell of the semiconductor device of FIG. 1.

FIG. 10 is a cross-sectional view illustrating a selector portion according to another embodiment of the present disclosure.

FIG. 11 is an energy band diagram illustrating an operation of the selector portion of FIG. 10.

FIG. 12 is a cross-sectional view illustrating a selector portion according to another embodiment of the present disclosure.

FIG. 13 is an energy band diagram illustrating an operation of the selector portion of FIG. 12.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

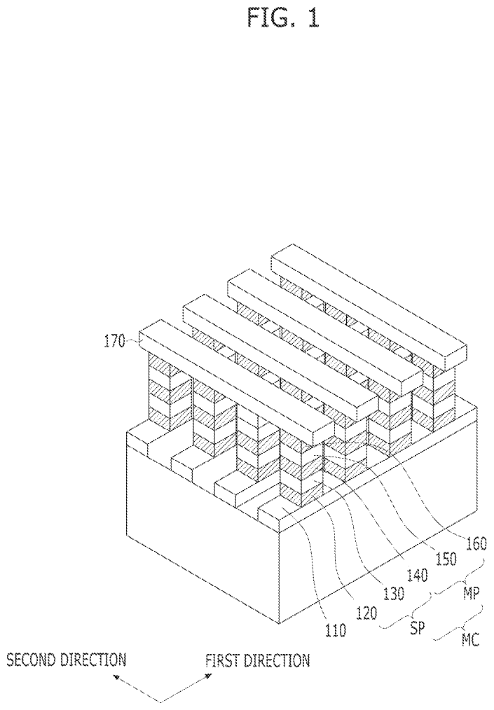

FIG. 1 is a perspective view illustrating a semiconductor device according to one example for implementing an embodiment of the present disclosure.

Referring to FIG. 1, the semiconductor device of the present embodiment may include a substrate 100, a plurality of first conductive lines 110 disposed over the substrate 100 and extending in a first direction to be parallel to each other, a plurality of second conductive lines 170 disposed over the first conductive lines 110 and extending in a second direction intersecting the first direction to be parallel to each other, and a plurality of memory cells MC interposed between the first conductive lines 110 and the second conductive lines 170 and overlapping intersection regions of the first conductive lines 110 and the second conductive lines 170, respectively.

The substrate 100 may include a semiconductor material such as silicon. Additionally, the substrate 100 may include any required substructure (not shown). As an example, the substrate 100 may include an integrated circuit for driving the first conductive line 110 and/or the second conductive line 170.

The first conductive line 110 and the second conductive line 170 may be connected to both ends of the memory cell MC, respectively. One of the first conductive line 110 and the second conductive line 170 may function as a word line and the other may function as a bit line. Each of the first conductive line 110 and the second conductive line 170 may include at least one of various conductive materials, for example, a metal such as platinum (Pt), tungsten (W), aluminum (Al), copper (Cu), tantalum (Ta), or titanium (Ti), a metal nitride such as titanium nitride (TiN), tantalum nitride (TaN), or tungsten nitride (WN), or a combination thereof, and may have a single-layer structure or a multi-layer structure.

The memory cell MC may have a pillar shape so as to overlap the intersection region between the first conductive line 110 and the second conductive line 170. In an example, the memory cell MC may have a square pillar shape in which both sidewalls in the first direction are aligned with both sidewalls of the second conductive line 170, and both sidewalls in the second direction are aligned with both sidewalls of the first conductive line 110. However, the present disclosure is not limited to this, and as long as the memory cell MC overlaps the intersection region between the first conductive line 110 and the second conductive line 170, the planar shape of the memory cell MC may be variously modified, such as circular, oval, polygonal, or others.

The memory cell MC may include a first electrode layer 120, a selector layer 130, a second electrode layer 140, a memory layer 150, and a third electrode layer 160. The first electrode layer 120, the selector layer 130, and the second electrode layer 140 may form a selector portion SP, and the second electrode layer 140, the memory layer 150, and the third electrode layer 160 may form a memory portion MP. The selector portion SP and the memory portion MP may share the second electrode layer 140. Thus, the second electrode layer 140 forms the memory portion together with the memory layer 150, and the third electrode layer 160. At the same time, the second electrode layer 140 forms the selector portion SP together with the first electrode layer 120 and the selector layer 130.

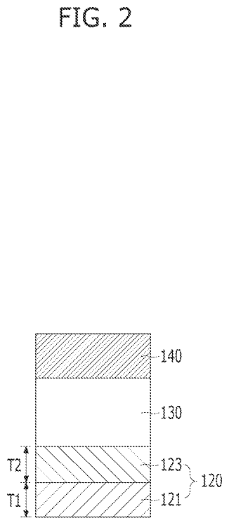

The first electrode layer 120 and the third electrode layer 160 may be located at the bottom and top of the memory cell MC, respectively, and may function as a path for transmitting a voltage or current. The second electrode layer 140 may physically separate but electrically connect the selector layer 130 and the memory layer 150, thereby functioning as a path for transmitting a voltage or current between the selector layer 130 and the memory layer 150. Each of the first electrode layer 120, the second electrode layer 140, and the third electrode layer 160 may independently include at least one of various conductive materials, for example, a metal such as platinum (Pt), tungsten (W), aluminum (Al), copper (Cu), tantalum (Ta), or titanium (Ti), a metal nitride such as titanium nitride (TiN), tantalum nitride (TaN), or tungsten nitride (WN), carbon, or a combination thereof, and may have a single-layer structure or a multi-layer structure. In particular, as described later with reference to an example in FIG. 2, the first electrode layer 120 may include a double-layer structure in which a first sub-electrode layer 121 and a second sub-electrode layer 123 are stacked.

The memory layer 150 may function to store data in various ways. As an example, the memory layer 150 may include a variable resistance layer that stores different data by switching between different resistance states depending on a voltage or current supplied through its top and bottom. The variable resistance layer may include at least one of various materials used in RRAM, PRAM, FRAM, MRAM, etc., for example, a metal oxide as a transition metal oxide or a perovskite-based material, a phase change material such as a chalcogenide-based material, a ferroelectric material, or a ferromagnetic material, and may have a single-layer structure or a multi-layer structure.

The selector layer 130 may control access to the memory layer 150, and may prevent and/or reduce current leakage that may occur between the memory cells MC sharing the first conductive line 110 or the second conductive line 170. To this end, the selector layer 130 may have threshold switching characteristics. Thus, the selector layer 130 may block or hardly flow current when the magnitude of the voltage supplied to its top and bottom is less than a predetermined threshold voltage, and may allow current to flow rapidly above this threshold voltage. Therefore, the selector layer 130 may be turned on at a voltage equal to or higher than the threshold voltage, and may be turned off at a voltage lower than the threshold voltage.

The selector layer 130 may include a diode, an OTS (Ovonic Threshold Switching) material such as a chalcogenide-based material, an MIEC (Mixed Ionic Electronic Conducting) material such as a metal-containing chalcogenide-based material, an MIT (Metal Insulator Transition) material such as NbO₂ or VO₂, or a tunneling insulating material with a relatively wide band gap such as SiO₂ or Al₂O₃.

In some implementations, the selector layer 130 may include an insulating material layer doped with a dopant. Here, the insulating material layer may include a silicon-containing insulating material such as silicon oxide, silicon nitride, or silicon oxynitride, an insulating metal oxide, an insulating metal nitride, or a combination thereof. There may be a deep trap within the insulating material layer having an energy level closer to the energy level of the valence band than the energy level of the conduction band of the insulating material layer. The dopant may serve to create a shallow trap that provides a path for the movement of conductive carriers, such as electrons or holes, within the insulating material layer. The shallow trap may have an energy level that is smaller than the work function of any one of the first and second electrode layers 120 and 140 and is closer to the energy level of the conduction band than the energy level of the valence band of the insulating material layer. In an example, when the insulating material layer contains silicon, the dopant may include a metal with a different valence than silicon, for example, gallium (Ga), boron (B), indium (In), phosphorus (P), arsenic (As), antimony (Sb), germanium (Ge), carbon (C), tungsten (W), or a combination thereof. Alternatively, when the insulating material layer contains a metal, the dopant may include another metal having a different valence than this metal or silicon. In an example, the selector layer 130 may include arsenic (As) doped silicon oxide, such as arsenic (As) doped silicon dioxide (SiO₂). When a voltage higher than the threshold voltage is applied to the selector layer 130, the carriers trapped in the deep trap may jump to the shallow trap by thermal emission or tunneling, and then, the carriers may move through the shallow trap, thereby creating a conductive path connecting the first electrode layer 120 and the second electrode layer 140. Thus, an on state in which current flows through the selector layer 130 may be implemented. On the other hand, when no voltage is applied to the selector layer 130 or a voltage less than the threshold voltage is applied to the selector layer 130, the phenomenon of the carriers jumping into the shallow trap may be reduced or prevented, and the conductive path may be broken. Thus, an off state in which no current flows through the selector layer 130 may be implemented.

In the present embodiment, the memory cell MC includes a stacked structure of the first electrode layer 120, the selector layer 130, the second electrode layer 140, the memory layer 150, and the third electrode layer 160, but the present disclosure is not limited thereto, and the layer structure of the memory cell MC may be modified in various ways. For example, at least one of the first electrode layer 120, the second electrode layer 140, and the third electrode layer 160 may be omitted. In an example, the upper and lower positions of the selector layer 130 and the memory layer 150 may be reversed with each other. In an example, the memory cell MC may further include one or more layers (not shown) to improve characteristics of the semiconductor device or facilitate manufacturing process.

In a semiconductor device, various implementations can be applied to improve characteristics of the selector layer 130. For example, various implementations on the material, structure, or other properties of the first electrode layer 120 and/or the second electrode layer 140, which is in contact with and/or connected to the selector layer 130, may be suggested to improve the characteristics of the selector layer 130. This is illustratively shown in more detail in FIG. 2.

FIG. 2 is a cross-sectional view showing an example of a selector portion of a memory cell of the semiconductor device of FIG. 1.

Referring to FIG. 2, in the present embodiment, the first electrode layer 120 may include a stacked structure of a first sub-electrode layer 121 and a second sub-electrode layer 123. The second sub-electrode layer 123 may be interposed between the first sub-electrode layer 121 and the selector layer 130, and thus, the second sub-electrode layer 123 may be located closer to the selector layer 130 than the first sub-electrode layer 121.

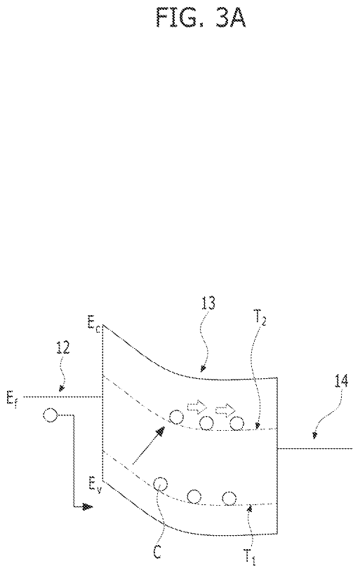

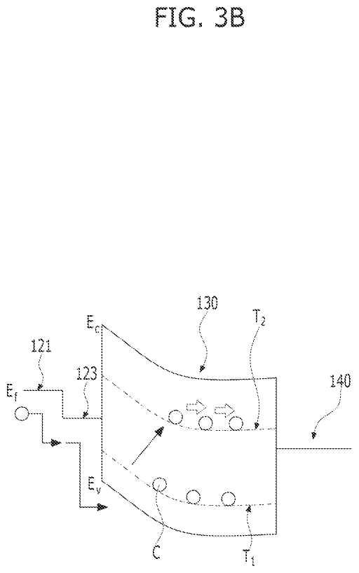

The second sub-electrode layer 123 may include a material having a work function greater than that of the first sub-electrode layer 121. As an example, the first sub-electrode layer 121 may include titanium nitride (TiN) with a work function of about 4.5 eV, and the second sub-electrode layer 123 may include molybdenum (Mo) with a work function of about 5.0 eV, molybdenum nitride (MoN), molybdenum oxide (MoO), or a combination thereof. In this case, the amount of the carriers moving from the first electrode layer 120 to the selector layer 130 may increase, so the density of the carriers in the selector layer 130 may increase. As a result, the selector layer 130 may become easier to turn on. Thus, the magnitude of the threshold voltage of the selector layer 130, which is needed to turn on the selector layer, may decrease. In some implementations, the speed of the turn-on operation of the selector layer 130 may increase. This will be described by way of example with reference to FIGS. 3A and 3B.

FIG. 3A is an example of an energy band diagram illustrating an operation of a selector portion of a comparative example, and FIG. 3B is an example of an energy band diagram illustrating an operation of a selector portion of the present embodiment, (e.g., the selector portion of FIG. 2). The selector portion of the comparative example may include a first electrode layer 12, a second electrode layer 14, and a selector layer 13 between them. Here, the first electrode layer 12 may have a single-layer structure containing the same material as the first sub-electrode layer 121 of FIG. 2, for example, titanium nitride. The second electrode layer 14 and the selector layer 13 may be substantially the same as the second electrode layer 140 and the selector layer 130 of FIG. 2. The selector layer 13 and the selector layer 130 may include an insulating material layer doped with a dopant, such as arsenic-doped silicon dioxide.

Referring to FIG. 3A, when a voltage is applied to the selector layer 13 through the first and second electrode layers 12 and 14, carriers C, such as electrons or holes, may be injected from the first electrode layer 12 to the selector layer 13, and may be trapped in a deep trap Ti. When the voltage applied to the selector layer 13 is greater than the threshold voltage, the carriers C in the deep trap T₁ may jump to the shallow trap T₂, and move through the shallow trap T₂ to form a conductive path connecting the first electrode layer 12 and the second electrode layer 14 in the selector layer 13.

Similarly, referring to FIG. 3B, when a voltage is applied to the selector layer 130 through the first and second electrode layers 120 and 140, carriers C may be injected from the first electrode layer 120 to the selector layer 130, and may be trapped in a deep trap Ti. When the voltage applied to the selector layer 130 is greater than the threshold voltage, the carriers C in the deep trap T₁ may jump to the shallow trap T₂, and move through the shallow trap T₂ form a conductive path connecting the first electrode layer 120 and the second electrode layer 140 in the selector layer 130.

In the comparative example, the carriers C may be injected by immediately exceeding the difference between the Fermi energy level Ef of the first electrode layer 12 and the valence band Ev of the insulating material layer forming the selector layer 13. On the other hand, in the present embodiment, since the work function of the second sub-electrode layer 123 is greater than the work function of the first sub-electrode layer 121, the Fermi energy level Ef of the second sub-electrode layer 123 may move further toward the valence band Ev of the insulating material layer forming the selector layer 130, compared to the first sub-electrode layer 121. Accordingly, in the present embodiment, the carriers C may be injected by exceeding the difference in the Fermi energy level Ef between the first sub-electrode layer 121 and the second sub-electrode layer 123, and the difference between the Fermi energy level Ef of the second sub-electrode layer 123 and the valence band Ev of the insulating material layer forming the selector layer 130 step by step. In this case, compared to the comparative example, the movement of the carriers C from the first electrode layer 120 to the selector layer 130 may be easier, so the density of the carriers C trapped in the deep trap T₁ of the selector layer 130 may increase. As a result, compared to the comparative example, the movement of the carriers C from the deep trap T₁ to the shallow trap T₂ of the selector layer 130 may become easier, so the threshold voltage for turning on the selector layer 130 can decrease or the turn-on operation speed of the selector layer 130 may increase.

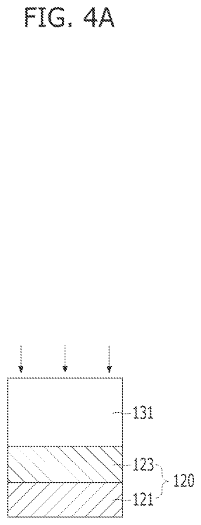

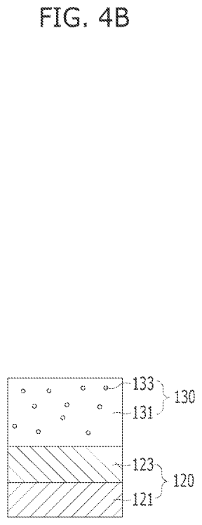

Referring back to FIG. 2, the density of the second sub-electrode layer 123 may be greater than the density of the first sub-electrode layer 121. In this case, the phenomenon of deterioration of the characteristics of the selector layer 130 due to diffusion of the dopant in the selector layer 130 to the outside may be reduced and/or prevented. Furthermore, the mass and/or size of at least one of the constituent elements of the second sub-electrode layer 123 may be greater than the mass and/or size of at least one of the constituent elements of the first sub-electrode layer 121. In this case, during the process of ion implanting the dopant into the insulating material layer to form the selector layer 130 (see FIG. 4A which is described later in this patent document), the dopant may be uniformly distributed within the insulating material layer, thereby improving the characteristics of the selector layer 130. This may be because, during the ion implantation process, the dopant cannot penetrate the second sub-electrode layer 123, which has a relatively large mass and/or size of the constituent elements, and is reflected from the second sub-electrode layer 123. If the second sub-electrode layer 123 is omitted, during the ion implantation process, the dopant may penetrate into the first sub-electrode layer 121, which has a relatively small mass and/or size of the constituent elements, so the dopant within the insulating material layer may not be distributed uniformly. When the first sub-electrode layer 121 includes titanium nitride and the second sub-electrode layer 123 includes molybdenum, these conditions that the density, the mass of the constituent elements, and the size of the constituent elements of the second sub-electrode layer 123 are greater than the density, the mass of the constituent elements, and the size of the constituent elements of the first sub-electrode layer 121 may be satisfied. However, the present disclosure is not limited to this, and the above-described advantages may be obtained when at least one of the density, the mass of the constituent elements, and the size of the constituent elements of the second sub-electrode layer 123 is greater than that of the first sub-electrode layer 121.

The first thickness T₁ of the first sub-electrode layer 121 and the second thickness T₂ of the second sub-electrode layer 123 may be substantially the same as each other. For example, the first thickness T₁ may have a value ranging from 90% to 110% of the second thickness T₂.

As discussed above, when the first electrode layer 120 includes a stacked structure of the first sub-electrode layer 121 and the second sub-electrode layer 123, and the work function of the second sub-electrode layer 123 is greater than that of the first sub-electrode layer 121, carrier injection into the selector layer 130 can be facilitated. In addition, when the first electrode layer 120 includes a stacked structure of the first sub-electrode layer 121 and the second sub-electrode layer 123, and at least one of the density, the mass of the constituent elements, and the size of the constituent elements of the second sub-electrode layer 123 is greater than at least one of the density, the mass of the constituent elements, and the size of the constituent elements of the first sub-electrode layer 121, sufficient dopants can be uniformly present in the selector layer 130, so the characteristics of the selector layer 130 can be improved.

FIGS. 4A and 4B are cross-sectional views illustrating an example of a method for forming the selector portion of FIG. 2.

Referring to FIG. 4A, the first sub-electrode layer 121 may be formed over a lower structure (not shown). The first sub-electrode layer 121 may be formed using at least one of various deposition methods. In an example, the first sub-electrode layer 121 may include titanium nitride formed by a physical vapor deposition (PVD) method.

Subsequently, the second sub-electrode layer 123 may be formed over the first sub-electrode layer 121. The second sub-electrode layer 123 may be formed using at least one of various deposition methods. For example, the second sub-electrode layer 123 may include molybdenum formed by an atomic layer deposition (ALD) method. The second sub-electrode layer 123 may have substantially the same thickness as the first sub-electrode layer 121.

Subsequently, an insulating material layer 131 may be formed over the second sub-electrode layer 123. As described above, the insulating material layer 131 may include a silicon-containing insulating material such as silicon oxide, silicon nitride, or silicon oxynitride, an insulating metal oxide, an insulating metal nitride, or a combination thereof, and may be deposited in various ways. In an example, the insulating material layer 131 may include silicon dioxide.

Subsequently, by performing ion implantation toward the insulating material layer 131 (see arrow), a dopant 133 may be doped into the insulating material layer 131. The result is shown in FIG. 4B.

Referring to FIG. 4B, the selector layer 130 may be formed by doping the insulating material layer 131 with the dopant 133. As described above, the dopant 133 may include an element that has a different valence from the constituent elements of the insulating material layer 131 and can form a shallow trap in the insulating material layer 131. For example, the dopant 133 may include gallium (Ga) and boron (B), indium (In), phosphorus (P), arsenic (As), antimony (Sb), germanium (Ge), carbon (C), tungsten (W), or silicon (Si). During the ion implantation process of FIG. 4A, the dopant 133 cannot penetrate the second sub-electrode layer 123, which has a large density, mass of constituent elements, and large size of constituent elements, so a sufficient amount of dopant 133 may be present in the selector layer 130, and the dopant 133 may be uniformly distributed.

Subsequently, although not shown, a selector portion may be formed by forming a second electrode layer over the selector layer 130.

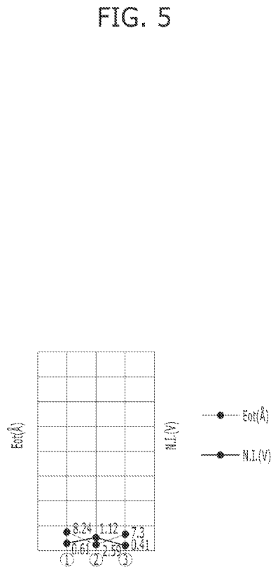

FIG. 5 is a view showing an effective thickness and leakage current characteristics of a selector portion in an example for implementing the present embodiment and comparative examples.

More specifically, a first case (see \textcircled{1}) in FIG. 5 may correspond to the present embodiment, and shows an effective thickness, Eot (effective oxide thickness), and leakage current characteristics N.I. when a selector layer is formed by forming arsenic doped silicon dioxide over a stacked structure of a TiN electrode layer and a Mo electrode layer. A second case (see \textcircled{2}) is one of the comparative examples, and shows an effective thickness Eot and leakage current characteristics N.I. when a selector layer is formed by forming arsenic doped silicon dioxide over a TiN electrode layer. A third case (see \textcircled{3}) is another one of the comparative examples, and shows an effective thickness Eot and leakage current characteristics N.I. when a selector layer is formed by forming arsenic doped silicon dioxide over a Mo electrode layer.

Referring to FIG. 5, it is seen that the effective thickness of the selector portion in the first case is greater than that in the second and third cases, and accordingly, the leakage current of the selector portion in the first case is smaller than that in the second and third cases. Thus, according to the present embodiment, it is possible to reduce the threshold voltage and improve the operating speed of the selector portion, while reducing the leakage current.

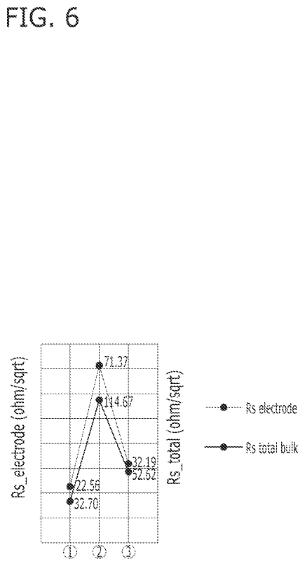

FIG. 6 is a view showing an example of a sheet resistance of an electrode of a selector portion and a sheet resistance of the selector portion as a whole in the present embodiment and comparative examples. In FIG. 6, the first case (see \textcircled{1}), the second case (see \textcircled{2}), and the third case (see \textcircled{3}) are the same as those described in FIG. 5.

Referring to FIG. 6, it is seen that the sheet resistance Rs of the electrode of the selector portion or the selector portion in the first case is smaller than that of the second and third cases. Thus, according to the present embodiment, the sheet resistance Rs of the selector portion can be reduced, and thus, it is possible to reduce the threshold voltage and improve the operating speed of the selector portion.

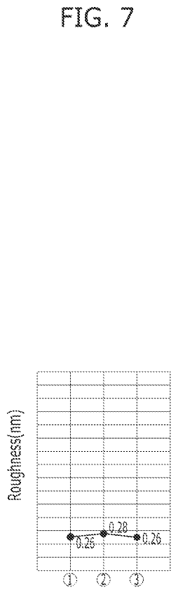

FIG. 7 is a view showing a roughness of a selector portion in one exemplary implementation of the present embodiment and comparative examples. In FIG. 7, the first case (see \textcircled{1}), the second case (see \textcircled{2}), and the third case (see \textcircled{3}) are the same as those described in FIG. 5.

Referring to FIG. 7, it is seen that there is no significant difference in roughness in the first case, second case, and third case. Thus, the roughness is not deteriorated even according to the present embodiment.

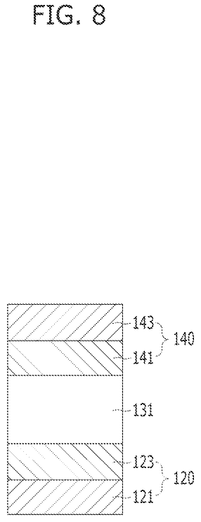

FIG. 8 is a cross-sectional view illustrating another example of a selector portion of a memory cell of the semiconductor device of FIG. 1. The description will focus on differences from the above-described embodiment.

Referring to FIG. 8, in the present embodiment, not only the first electrode layer 120 but also the second electrode layer 140 may have a double-layer structure. Thus, the second electrode layer 140 may include a stacked structure of a third sub-electrode layer 141 and a fourth sub-electrode layer 143. The third sub-electrode layer 141 may be interposed between the fourth sub-electrode layer 143 and the selector layer 130, and thus, the third sub-electrode layer 141 may be located closer to the selector layer 130 than the fourth sub-electrode layer 143.

The third sub-electrode layer 141 may include substantially the same material as the second sub-electrode layer 123, and the fourth sub-electrode layer 143 may include substantially the same material as the first sub-electrode layer 121. For example, the third sub-electrode layer 141 may include molybdenum, and the fourth sub-electrode layer 143 may include titanium nitride. Accordingly, the work function, density, mass of constituent elements, and/or size of the constituent elements of the third sub-electrode layer 141 may be greater than, respectively, the work function, density, mass of constituent elements, and/or size of the constituent elements of the fourth sub-electrode layer 143. In this case, diffusion of the dopant in the selector layer 130 to the outside may be further prevented and/or reduced.

In some implementations, the third sub-electrode layer 141 may have substantially the same thickness as the second sub-electrode layer 123, and the fourth sub-electrode layer 143 may have substantially the same thickness as the first sub-electrode layer 121. Thus, the first and second sub-electrode layers 121 and 123 and the third and fourth sub-electrode layers 141 and 143 may be symmetrical to each other with the selector layer 130 interposed therebetween.

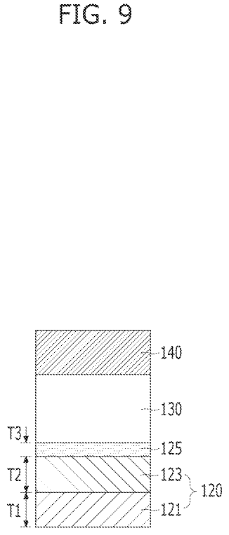

FIG. 9 is a cross-sectional view illustrating another example of a selector portion of a memory cell of the semiconductor device of FIG. 1. The description will focus on differences from the above-described embodiment.

Referring to FIG. 9, in the present embodiment, an adhesive layer 125 may be interposed between the first electrode layer 120 and the selector layer 130.

The adhesive layer 125 may function to improve adhesion characteristics between the first electrode layer 120, particularly, the second sub-electrode layer 123 and the selector layer 130. The adhesive layer 125 may include at least one of various materials containing a non-conductive element, such as SiB, SiCN, SiO₂, SiN, SiBN, or combinations thereof. When the adhesive layer 125 contains a non-conductive element, the constituent elements of the adhesive layer 125 may not participate in the operation of the selector layer 130 even if the constituent elements of the adhesive layer 125 are present in the selector layer 130 formed as a result of the ion implantation process. In an example, the adhesive layer 125 may include silicon nitride (SiN). The thickness T3 of the adhesive layer 125 may be smaller than the thickness T1 of the first sub-electrode layer 121 and/or the thickness T3 of the second sub-electrode layer 123.

In addition, although not shown, an adhesive layer may be further interposed between the second electrode layer 140 and the selector layer 130.

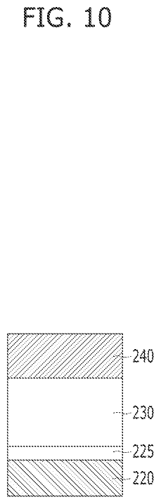

In the above embodiments, the electrode layer connected to the selector layer are formed to have double layers with different work functions to increase the amount of carriers injected into the selector layer, but the present disclosure is not limited to this. The amount of carriers injected into the selector layer may be increased by interposing a material layer having a smaller band gap than the insulating material layer forming the selector layer between the selector layer and the electrode layer. This will be exemplarily explained with reference to FIGS. 10 to 13 below.

FIG. 10 is a cross-sectional view illustrating a selector portion according to an example for implementing another embodiment of the present disclosure.

Referring to FIG. 10, the selector portion of the present embodiment may include a first electrode layer 220, a selector layer 230, a second electrode layer 240, and a material layer 225 interposed between the selector layer 230 and the first electrode layer 220.

Unlike the above-described embodiment of FIG. 2, the first electrode layer 220 may have a single-layer structure. For example, the first electrode layer 220 may include titanium nitride. The first electrode layer 220 may be formed of or include the same material and/or the same thickness as the second electrode layer 240. The second electrode layer 240 and the selector layer 230 may be substantially the same as the second electrode layer 140 and the selector layer 130 of the embodiment of FIG. 2.

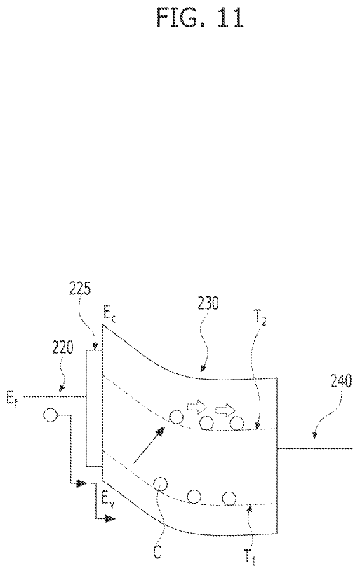

The material layer 225 may include any material having a band gap smaller than that of the insulating material layer forming the selector layer 230. As an example, when the insulating material layer forming the selector layer 230 is silicon dioxide, the material layer 225 may include an insulating material or semiconductor material with a bandgap smaller than that of silicon dioxide, for example, Ta₂O₅, ZrO₂, HfO₂, Y₂O₃, SiN, SrTiO₃, or others. Additionally, the material layer 225 may have a thinner thickness than the thickness of the first electrode layer 220, the second electrode layer 240, and the selector layer 230. Although not shown, the material layer 225 may be further interposed between the second electrode layer 240 and the selector layer 230. In this case, the amount of carriers moving from the first electrode layer 220 to the selector layer 230 may increase, so the density of carriers in the selector layer 230 may increase. As a result, it may be easier to turn on the selector layer 230. This will be described by way of example with reference to FIG. 11.

FIG. 11 is an energy band diagram illustrating an operation of the selector portion of FIG. 10.

Referring to FIG. 11, when a voltage is applied to the selector layer 230 through the first and second electrode layers 220 and 240, carriers C may be injected from the first electrode layer 220 into the selector layer 230 to be trapped within a deep trap Ti. When the voltage applied to the selector layer 230 is greater than the threshold voltage, the carriers C in the deep trap T₁ may jump to the shallow trap T₂, and may move through the shallow trap T₂, thereby forming a conductive path connecting the first electrode layer 220 and the second electrode layer 240 in the selector layer 230.

Here, the band gap of the material layer 225 may be smaller than the band gap of the insulating material layer forming the selector layer 230, so the energy of the valence band of the material layer 225 may be greater than the energy of the valence band of the insulating material layer forming the selector layer 230. Accordingly, the carriers C may be injected to the selector layer by exceeding the difference between the Fermi energy level Ef of the first electrode layer 220 and the valence band of the material layer 225, and the difference between the valence band of the material layer 225 and the valence band of the insulating material layer forming the selector layer 230, step by step. In this case, compared to a case where the material layer 225 is omitted, the movement of the carriers C from the first electrode layer 220 to the selector layer 230 becomes easier, and therefore, the density of the carriers C trapped in the deep trap T₁ may increase. As a result, compared to the case where the material layer 225 is omitted, the movement of the carriers C from the deep trap T₁ to the shallow trap T₂ may become easier, and thus, the threshold voltage for turning on the selector layer 230 may decrease and the turn-on operation speed of the selector layer 230 may increase.

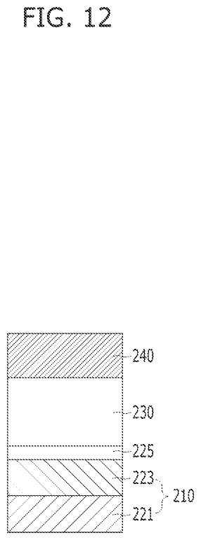

FIG. 12 is a cross-sectional view illustrating a selector portion according to an example for implementing another embodiment of the present disclosure.

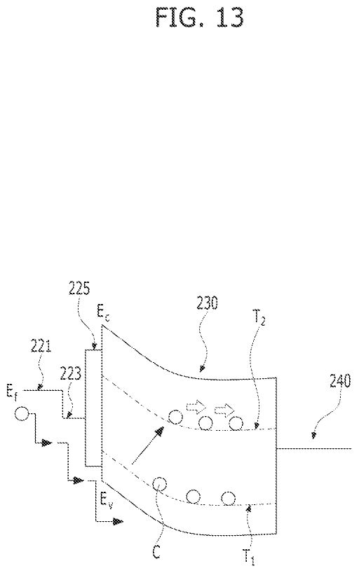

Referring to FIG. 12, the selector portion of the present embodiment may include a first electrode layer 220, a selector layer 230, a second electrode layer 240, and a material layer 225 interposed between the selector layer 230 and the first electrode layer 220. Here, the first electrode layer 220 may include a stacked structure of the first sub-electrode layer 221 and the second sub-electrode layer 223, substantially the same as that described in the embodiment of FIG. 2. In this case, the amount of carriers moving from the first electrode layer 220 to the selector layer 230 can increase, so the density of carriers in the selector layer 230 can increase. As a result, it can be easier to turn on the selector layer 230. This will be described by way of example with reference to FIG. 13. Here, the material layer 225 may have a thinner thickness than the thickness of the first sub-electrode layer 221 and the second sub-electrode layer 223.

FIG. 13 is an example of an energy band diagram illustrating an operation of the selector portion of FIG. 12.

Referring to FIG. 13, when a voltage is applied to the selector layer 230 through the first and second electrode layers 220 and 240, carriers C may be injected from the first electrode layer 220 into the selector layer 230 to be trapped within the deep trap T₁. When the voltage applied to the selector layer 230 is greater than the threshold voltage, the carriers C in the deep trap T₁ may jump to the shallow trap T₂, and may move through the shallow trap T₂ to form a conductive path connecting the first electrode layer 220 and the second electrode layer 240 in the selector layer 230.

Here, since the work function of the second sub-electrode layer 223 is greater than the work function of the first sub-electrode layer 221, the Fermi energy level Ef of the second sub-electrode layer 223 may move further toward the valence band Ev of the insulating material layer forming the selector layer 230, compared to the first sub-electrode layer 221. In addition, since the band gap of the material layer 225 is smaller than the band gap of the insulating material layer forming the selector layer 230, the energy of the valence band of the material layer 225 may be greater than the energy of the valence band of the insulating material layer forming the selector layer 230. Accordingly, in the present embodiment, the carriers C may be injected by exceeding the difference in the Fermi energy level Ef between the first sub-electrode layer 221 and the second sub-electrode layer 223, the different between the Fermi energy level Ef of the second sub-electrode layer 223 and the valence band of the material layer 225, and the difference between the valence band of the material layer 225 and the valence band of the insulating material layer forming the selector layer 230, step by step. In this case, it may be easier to move the carriers C from the first electrode layer 220 to the selector layer 230, compared to a case where the material layer 225 and/or the second sub-electrode layer 223 is omitted, so the density of carriers C trapped within the deep trap T₁ may increase. As a result, compared to the case where the material layer 225 and/or the second sub-electrode layer 223 is omitted, the movement of the carriers C from the deep trap T₁ to the shallow trap T₂ may become easier, the threshold voltage for turning on the selector layer 230 may decrease and the turn-on operation speed of the selector layer 230 may increase.

According to the above embodiments of the present disclosure, it may be possible to provide a semiconductor device capable of improving characteristics a selector of a memory cell.

Although various embodiments have been described for illustrative purposes, it will be apparent to those skilled in the art that various changes and modifications to the disclosed examples or embodiments and/or other embodiments may be made based on what is described and/or illustrated in this patent document.

What is claimed is:

1. A semiconductor device comprising a plurality of memory cells for storing data, each of the plurality of memory cells comprising:
a first electrode layer;
a second electrode layer;
a memory layer electrically connected to the second electrode layer and configured to store data;
a selector layer interposed between the first electrode layer and the second electrode layer and configured to control an access to the memory layer, the selector layer including an insulating material layer doped with a dopant,
wherein at least one of the first electrode layer and the second electrode layer includes a first sub-electrode layer, and a second sub-electrode layer interposed between the first sub-electrode layer and the selector layer and including a material having a work function greater than a work function of the first sub-electrode layer.

2. The semiconductor device according to claim 1, wherein at least one of a density, a mass of a constituent element, or a size of the constituent element of the second sub-electrode layer is greater than, respectively, a density, a mass of a constituent element, or a size of the constituent element of the first sub-electrode layer.

3. The semiconductor device according to claim 1, wherein the first sub-electrode layer includes a titanium nitride, and the second sub-electrode layer includes a molybdenum.

4. The semiconductor device according to claim 1, wherein a thickness of the first sub-electrode layer has a value of 90 to 110 percent of a thickness of the second sub-electrode layer.

5. The semiconductor device according to claim 1, wherein the dopant forms a shallow trap within the insulating material layer, the shallow trap having an energy level closer to a conduction band of the insulating material layer than a valence band of the insulating material layer, and
a movement path for conductive carriers is formed through the shallow trap.

6. The semiconductor device according to claim 1, wherein the selector layer includes an arsenic-doped silicon oxide.

7. The semiconductor device according to claim 1, further comprising:
an adhesive layer interposed between the second sub-electrode layer and the selector layer.

8. The semiconductor device according to claim 1, further comprising:
a material layer interposed between the second sub-electrode layer and the selector layer and having a band gap smaller than a band gap of the insulating material layer.

9. The semiconductor device according to claim 8, wherein a thickness of the material layer is smaller than a thickness of the first sub-electrode layer, a thickness of the second sub-electrode layer, or a thickness of the selector layer.

10. The semiconductor device according to claim 8, wherein the material layer includes an insulating material or a semiconductor material.

11. A semiconductor device comprising a plurality of memory cells for storing data, each of the plurality of memory cells comprising:
a first electrode layer;
a second electrode layer;
a memory layer electrically connected to the second electrode layer and configured to store data;
a selector layer interposed between the first electrode layer and the second electrode layer and configured to control an access to the memory layer, the selector layer including an insulating material layer doped with a dopant;
a material layer located at least one of a first location between the first electrode layer and the selector layer or a second location between the second electrode layer and the selector layer, and having a band gap smaller than a band gap of the insulating material layer.

12. The semiconductor device according to claim 11, wherein a thickness of the material layer is smaller than a thickness of the first electrode layer or a thickness of the second electrode layer.

13. The semiconductor device according to claim 11, wherein the material layer includes an insulating material or a semiconductor material.

14. The semiconductor device according to claim 11, wherein the dopant forms a shallow trap within the insulating material layer, the shallow trap having an energy level closer to a conduction band of the insulating material layer than a valence band of the insulating material layer, and
a movement path for conductive carriers is formed through the shallow trap.

15. The semiconductor device according to claim 11, wherein the selector layer includes an arsenic-doped silicon oxide.

16. A semiconductor device comprising a plurality of memory cells for storing data, each of the plurality of memory cells comprising:
a first electrode layer;
a second electrode layer;
a memory layer electrically connected to the second electrode layer and configured to store data; and
a selector layer interposed between the first electrode layer and the second electrode layer and configured to control an access to the memory layer, the selector layer including an insulating material layer doped with a dopant,
wherein at least one of the first electrode layer and the second electrode layer includes a first sub-electrode layer and a second sub-electrode layer interposed between the first sub-electrode layer and the selector layer, and
at least one of a density, a mass of a constituent element, or a size of the constituent element of the second sub-electrode layer is greater than, respectively, a density, a mass of a constituent element, or a size of the constituent element of the first sub-electrode layer.

17. The semiconductor device according to claim 16, wherein the first sub-electrode layer includes a titanium nitride, and the second sub-electrode layer contains a molybdenum.

18. The semiconductor device according to claim 16, wherein a thickness of the first sub-electrode layer has a value of 90 to 110 percent of a thickness of the second sub-electrode layer.

19. The semiconductor device according to claim 16, further comprising:
an adhesive layer interposed between the second sub-electrode layer and the selector layer.

20. The semiconductor device according to claim 16, further comprising:
a material layer interposed between the second sub-electrode layer and the selector layer and having a band gap smaller than a band gap of the insulating material layer.
